(19) United States
(12) Patent Application Publication
(10) Pub. No.: US 2009/0161239 A1
(43) Pub. Date: Jun. 25, 2009

(54) CAMERA DIAPHRAGM AND LENS POSITIONING SYSTEM EMPLOYING A DIELECTRICAL POLYMER ACTUATOR

(75) Inventors: Boudewijn Verhaar, Eindhoven (NL); Bart Dirkx, Eindhoven (NL); Michael Bauer, Jena (DE); Funda Sahin Nomaler, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 12/158,351

(22) PCT Filed: Dec. 18, 2006
(86) PCT No.: PCT/IB06/54933

§ 371 Date: Jun. 20, 2008

Related U.S. Application Data
(60) Provisional application No. 60/752,096, filed on Dec. 20, 2005.

(51) Int. Cl. G02B 7/09; H02N 2/04; H01L 41/22; G03B 9/02

(52) U.S. Cl. 359/824; 310/348; 29/25.35; 396/170

(57) ABSTRACT

An electroactive polymer actuator (10) is disclosed for use in various applications including camera diaphragms and lenses. The actuator (10) converts electrical energy to mechanical energy and comprises, in one embodiment, at least two flexible electrodes (15, 25); a transparent elastic non-conductive material (20) having a substantially constant thickness, the transparent elastic non-conductive material (20) arranged in a manner which causes the transparent elastic non-conductive material (20) to compress in a first direction orthogonal to the thickness in response to an electric field applied to the polymer; and a frame coupled to the at least two electrodes (15, 25) and the transparent elastic non-conductive material (20), the outer frame substantially preventing expansion in a second direction opposite said first direction in response to an electric field applied to the polymer.

The present invention relates generally to electroactive polymers that convert between electrical energy and mechanical energy. More particularly, the present invention relates to electroactive polymers and their use in various applications.

In many applications, it is desirable to convert between electrical energy and mechanical energy. Such applications include, for example, robotics, pumps, speakers, disk drives and camera lenses. These applications include one or more actuators that convert electrical energy into mechanical work, on a macroscopic or microscopic level. As is well known, actuators are the counterpart of sensors in a control loop that transfer electrical or thermal energy into mechanical work.

Common electric actuator technologies suffer from a number of drawbacks. In the case of a camera lens actuating device, the device is mechanically complex and includes a relatively large diaphragm or lens with variable position. The mechanical complexity makes the device failure sensitive.

A variety of electromechanical actuators based on the principal that certain types of polymers can change shape under certain conditions of stimulation have been under investigation for decades. This research was organized by Yoseph Bar-Cohen in a book entitled “Electroactive Polymer (EAP) Actuators as Artificial Muscles: Reality, Potential and Challenges” (SPIE Press, January 2001). Electro active polymers (EAP) represent a promising type of actuator, whereby motion is generated by changing its shape or mechanical properties, thereby obviating the problems associated with the more mechanically complex, and heavy conventional electric actuator technologies.

Given the above listed and other challenges and shortcomings of conventional electromechanical actuators, there remains a need for instruments that more fully realize the advantages of activated polymers and activated polymer based actuators.

In view of the above problems, a concern of the present invention is to provide an electroactive polymer actuator, which includes the capability of improving response speed and operation reliability of a device using electroactive effect.

In one aspect, the present invention relates to polymers that convert between electrical and mechanical energy. When a voltage is applied to electrodes contacting a polymer, which may be pre-strained, the polymer deflects. This deflection may be used to do mechanical work. In one aspect, the present invention relates to polymers that are pre-strained to improve conversion between electrical and mechanical energy. When a voltage is applied to electrodes contacting a pre-strained polymer, the polymer deflects. This deflection may be used to do mechanical work. The pre-strain improves the mechanical response of an electroactive polymer relative to a non-strained polymer. The pre-strain may vary in different directions of a polymer to vary response of the polymer to the applied voltage. In certain embodiments, the polymers are not pre-strained. In certain other embodiments, pre-strain may be maintained with an elastic element at the inner diameter of the electrodes.

In one aspect of the invention, the present invention relates to an actuator for converting electrical energy into displacement in a first direction. The actuator comprises a circular sheet of elastic, di-electric, transparent polymer material such as Acrylic Tape 4910, Silicone CF19-2186 and Silicone HS III, a first ring-shaped flexible electrode formed on an upper surface of the laminate, and a second ring-shaped flexible electrode formed on a bottom surface of the laminate. The actuator further comprises a voltage applying unit for applying a voltage between the first and second electrodes to cause the laminate to be displaced in response to a change in electric field provided by at least two electrodes. The actuator further comprises a ring-shaped rigid frame coupled to the laminate, the frame providing mechanical assistance to maintain the pre-strain and to ensure displacement in a first direction.

In another aspect, the present invention relates to an actuator for converting electrical energy into linear displacement in a first direction. The actuator comprises a pre-stretched di-electric polymer material with upper and lower electrode layers in the shape of a membrane or diaphragm. The actuator further comprises two rigid round outer plastic rings that attach to the membrane, e.g., in a sandwich configuration. The two rigid round rings providing mechanical assistance to ensure displacement along an axis orthogonal to the plane of the membrane.

In another embodiment, the actuator may further comprise two small non-conducting non-flexible round inner rings that attach to the center of the membrane thereby forming a hole in the center of the membrane.

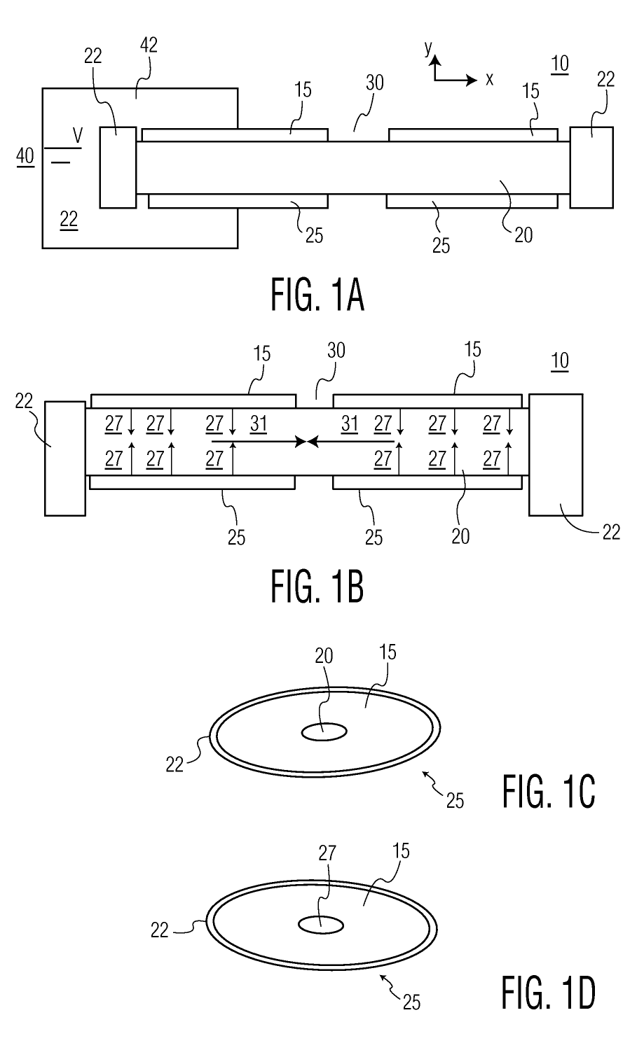

FIGS. 1A-1D are cross-section and perspective views of an electroactive polymer actuator according to a first embodiment of the present invention,

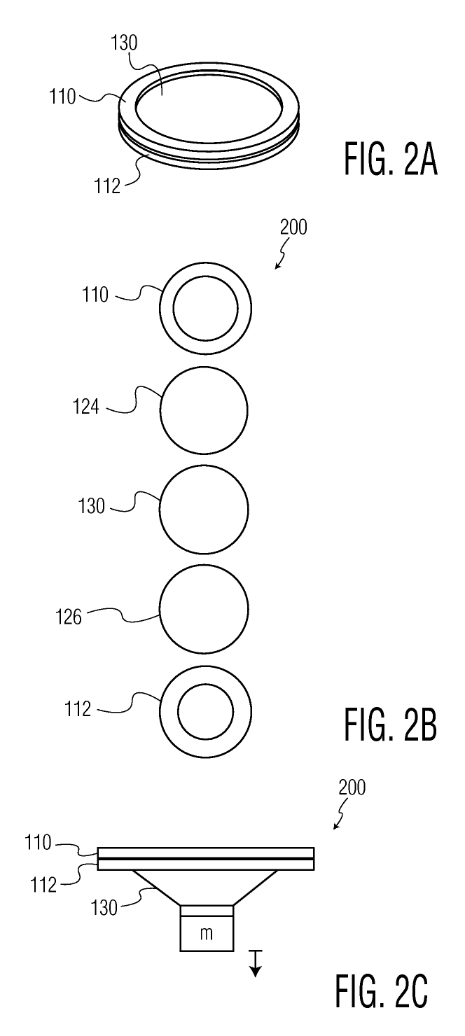

FIGS. 2A and 2B are cross-section views of an electroactive polymer actuator according to a second embodiment of the present invention,

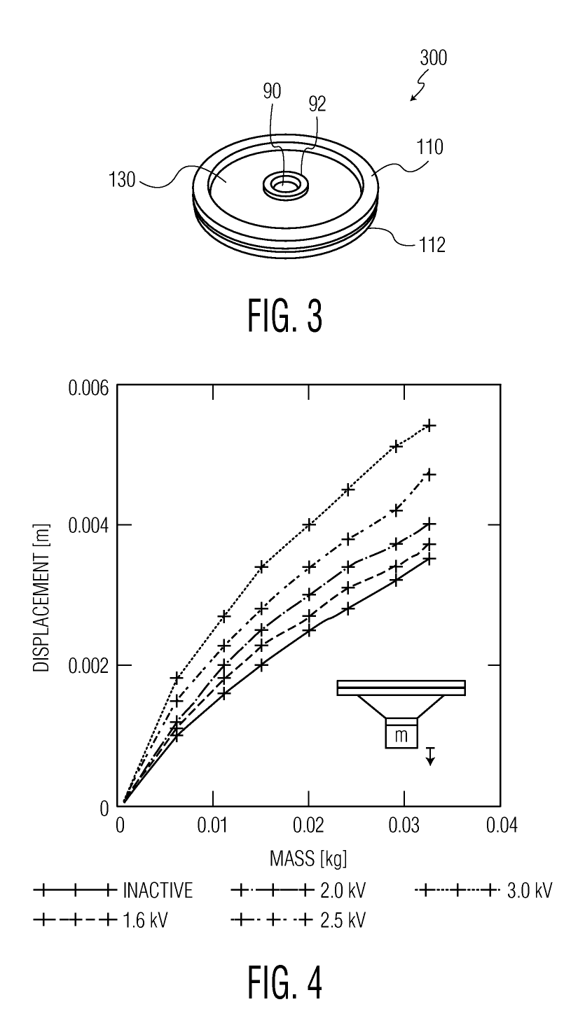

FIG. 3 illustrates the membrane actuator shown in FIGS. 2A and 2B, further including a stiff non-conducting inner ring,

FIG. 4 is a diagram showing on a linear scale (meters), a graph of displacement (m) versus Mass (kg) for an applied electric field measurement for a special test construction in which different masses or loads (kg) are attached to the inner ring of the membrane actuator of FIG. 3,

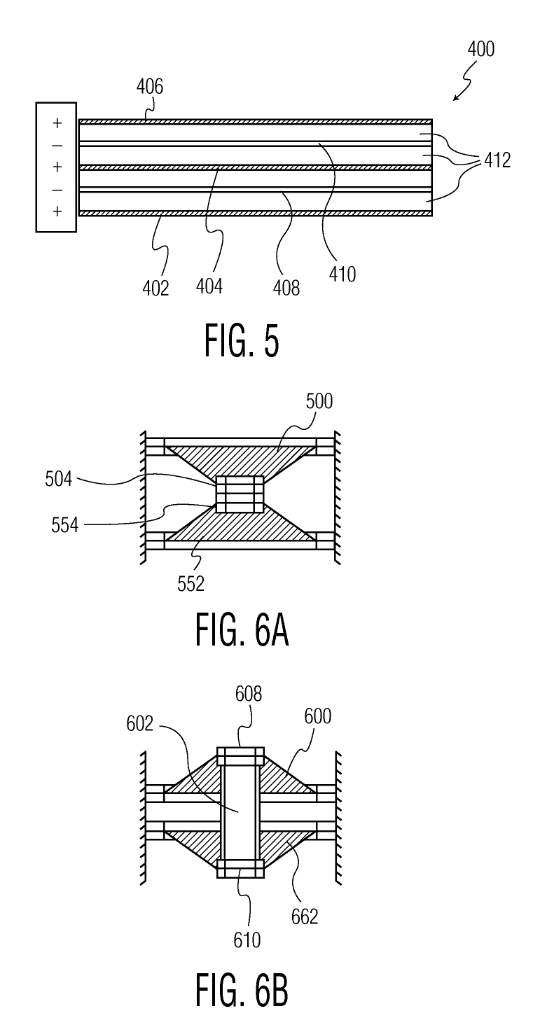

FIG. 5 illustrates a non-limiting example of a laminated polymer stack comprising additional electrode layers arranged such that alternate layers are connected to a common electrode (+/−),

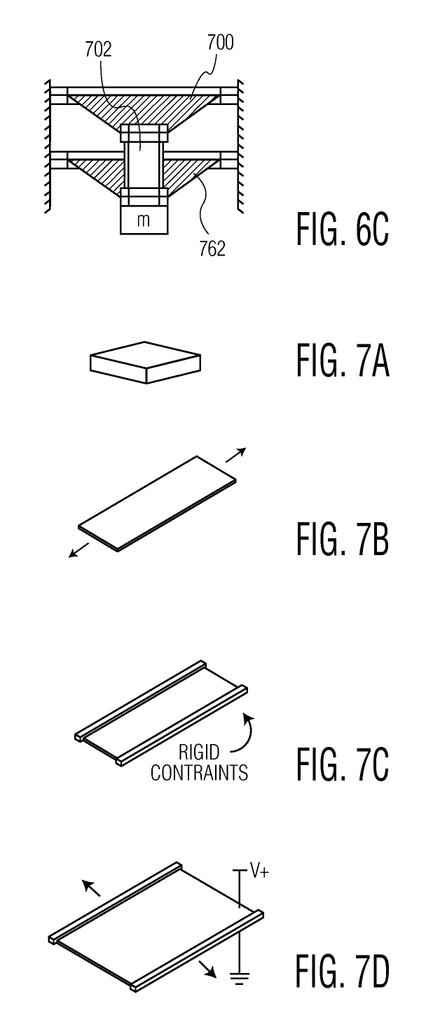

FIGS. 6A-6C are cross-sectional views illustrating how several membrane actuators can be combined to increase the absolute movement or force under application of a voltage,

FIG. 7A-7D, illustrate how an actuator deforms in a single direction upon application of an electric field,

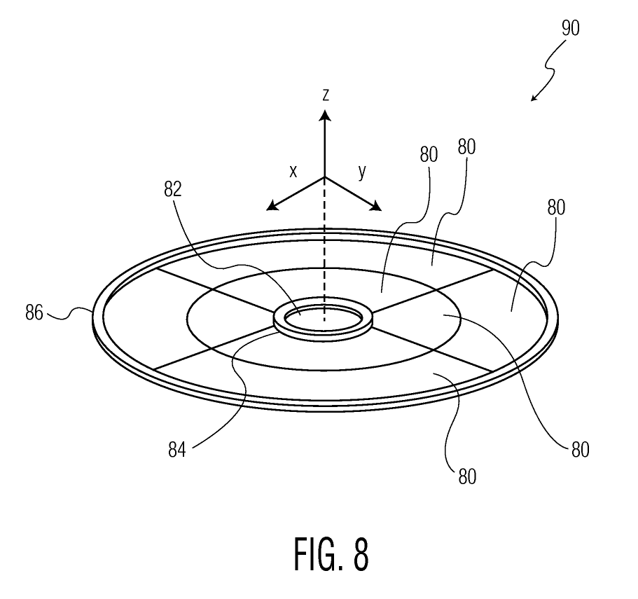

FIG. 8 is an illustration of a conductive layer comprised of multiple segments.

Electroactive polymers of the present invention may be used as an actuator to convert from electrical to mechanical energy. For a polymer having a substantially constant thickness, polymers of the present invention perform as an actuator by experiencing a displacement either along the axis of thickness (i.e., parallel to a cross-section of the polymer) or orthogonal to the axis of thickness during use (i.e., perpendicular to a cross-section of the polymer). For these polymers, when a displacement occurs, the polymer is acting as an actuator.

It should be noted that while the disclosed embodiments illustrate actuators having a circular shape, the present invention contemplates the use of actuators having other shapes. For example, other shapes may include, without limitation, squares, rectangles, pentagons, hexagons, octagons and so on. The actuator shape being determined primarily from its intended use.

It should be noted that while the disclosed embodiments illustrate actuators employing elastic, non-conducting, di-electric polymers, the present invention also contemplates the use of actuators employing materials other than non-conducting, di-electric polymers (e.g. visco-elastic materials, fluids, and so on)

It should be noted that while the disclosed embodiments illustrate actuators having pre-strained polymers, the present invention contemplates the use of actuators having non-prestrained polymers.

In the embodiments described herein, a di-electric transparent elastic non-conductive material may comprise different materials including, without limitation, Acrylic Tape 4910, manufactured by the 3M Corporation, Silicone CF 19-2186 from Nusil and Silicone HS III from Dow Corning.

### FIRST EMBODIMENT

FIGS. 1A and 1B illustrate cut away views of an electroactive polymer actuator 10, according to the first embodiment. The actuator 10 comprises a flexible upper ring electrode 15 on a top surface of an elastic, di-electric, transparent elastic non-conductive material 20, referred to hereafter as a polymer material 20. The polymer material may be pre-strained. The electroactive polymer actuator 10 further includes a flexible lower ring electrode 25 on a bottom surface of the transparent polymer material 20. The flexible electrodes 15, 25 may be applied to the polymer material 20 in a number of ways, including, without limitation, painting or coating the polymer material 20 on its upper and lower surface with a flexible conductive material or using graphite powder. Of course, other techniques, well known in the art, not explicitly recited herein, may be used to apply the electrodes 15, 25 to the polymer material 20. In the present embodiment, the upper and lower ring electrodes 15, 25 are positioned to cover a substantial portion of the respective upper and lower surfaces of the polymer material 20, leaving an exposed circular portion 30 (see FIGS. 1C and 1D) substantially in the center of the polymer material 20.

As shown in FIG. 1A, the electroactive polymer actuator 10 has a voltage applying unit (DC power supply) 40 for applying a voltage between the upper and lower ring electrodes 15, 25 to thereby cause a stationary displacement or movement in the polymer material 20. In other embodiments, the voltage source may be an AC signal source to obtain stationary displacement or movement patterns in the polymer material 20.

In the present embodiment, the upper ring electrode 15 is connected to the positive pole of the DC power supply 40, and the lower ring electrode 25 is connected to the negative pole of the DC power supply 40. The power supply may be an AC power supply in other embodiments. In the present embodiment, the electroactive polymer actuator 10 further comprises an outer circular frame 22 which is rigidly attached to the two electrodes 15, 25 and the polymer material 20 substantially at its ends.

Referring now to FIG. 1B, in the electroactive polymer actuator 10 having the above structure, when a switch 42 is turned on, a deformation in the polymer material 20 is such that the dimension in the y-direction of the polymer material 20 compresses or decreases, as indicated in FIG. 1B by the compression arrows 27. It should be recognized that by virtue of holding the outer diameter of the polymer material 20 constant by the outer circular frame 22, the polymer material 20 is forced to expand in the direction of the inner diameter of the lower and upper ring electrodes 15, 25, as shown by the two expansion arrows labeled 31. In other words, expansion of the polymer material occurs in the direction of the exposed circular portion 30 which is orthogonal to the thickness of the polymer material 20. Stated differently, the direction of expansion of the polymer material 20 can be considered as being perpendicular to a cross-section of the polymer material 20.

In one exemplary application of the electroactive polymer actuator 10 of FIG. 1 having the above structure, the inventors have recognized that the electroactive polymer actuator 10 is suitable for use as a camera aperture or diaphragm. In such an application, the polymer material 20 is fully transparent, and the flexible ring electrodes 15 and 25 are non-transparent. As shown in perspective view in FIG. 1C, the inner diameter of both flexible non-transparent ring electrodes 15 and 25 form an aperture diameter of a camera diaphragm, substantially in the center region 30. Whenever a voltage is applied, or increased, between the upper and lower ring electrodes 15, 25, the aperture diameter is reduced (i.e., controlled) as a consequence of the polymer material 20 being compressed thus performing a function associated with a camera aperture.

In another related exemplary application, the polymer 20, which may be non-transparent, may further comprises a hole substantially in the center region 30. For this application, the hole 30 forms the aperture diameter of a camera diaphragm. Whenever a voltage is applied, or increased, between the upper and lower ring electrodes 15, 25, the aperture diameter 30 (i.e., hole diameter) is reduced (i.e., controlled) thus performing a function associated with a camera aperture or diaphragm.

### SECOND EMBODIMENT

As shown in FIG. 2A, a membrane actuator 200 is shown in a perspective view. In its overall construction, the membrane actuator 200 has a structure comprised of an elastic non-conductive material 130, referred to hereafter as a di-electric polymer material, which serves as a membrane or diaphragm, and top and bottom, circular, stiff, non-conducting rings 110, 112. The top and bottom rings 110, 112 hold the di-electric polymer material 130 pre-stretched and are preferably constructed of a stiff plastic.

As shown in FIG. 2B, the di-electric polymer material 130 includes two conducting layers 124, 126, comprised of a conducting material (e.g., graphite), which may be painted or coated to the top and bottom surface of the di-electric polymer material 130, as described above with reference to the first embodiment. In contrast with the first embodiment, however, the electrodes 124, 126 of the present embodiment do not form a ring shape. Instead, the upper and lower electrodes 124, 126 coat the entire surface of the di-electric polymer material 130. When a voltage is applied to both sides of the upper and lower electrodes 124, 126, the di-electric polymer material 130 expands in a manner causing the polymer material 130 to have a convex shape via the displacement of an attached spring or load (m) 133, as shown in FIG. 2C.

Primary parameters considered in the choice of a di-electric polymer material 130 include the di-electric constant, the Young's Module and the di-electric strength after pre-strain. In certain embodiments, an additional layer of polymer material 130 may be used to form a kind of laminate to protect the di-electric polymer material 130 from being deformed by small scratches or sharp corners which may occur on the top and bottom rings 110, 112.

### THIRD EMBODIMENT

As shown in FIG. 3, a membrane actuator 300 of the third embodiment is similar in construction to the membrane actuator of the second embodiment, as shown in FIGS. 2A and 2B, in most respects. For example, the membrane actuator 300 includes to p and bottom rings 110, 112 for holding the di-electric polymer material 130 pre-stretched and are preferably constructed of a stiff plastic. The membrane actuator 300 of FIG. 3 differs from the previously described membrane actuator 200 in one important aspect. Specifically, the membrane actuator 300 of the present embodiment, further comprises a stiff non-conducting inner ring 90 which forms a hole 92 in the center of the membrane actuator 300. The inner ring 90 facilitates the attachment of different masses (loads) or springs to the membrane actuator 300 to ensure that deformation occurs in a desired direction under the application of an electric field. It should be appreciated that the inner ring 90 further facilitates testing of the membrane actuator 300.

In membrane actuators 300 having the above structure, when a switch is turned on, a deformation in the di-electric polymer material 130 is such that the dimension in an axial direction (+/−Z) expands, such that the polymer material 130 forms a convex shape.

FIG. 4 is a diagram showing on a linear scale (meters), a graph of displacement (m) versus Mass (kg) for an applied electric field measurement for a special test construction in which different masses or loads (kg) are attached to the inner ring 90 of the membrane actuator 300 illustrated in FIG. 3. As shown, the graph exhibits a non-linearity and saturation at higher displacements. It should be understood that it is desirable to operate the membrane actuator 300 in the linear region. As such, it is desirable to use polymer materials that increase the linear operating region. Of course, those skilled in the art will recognize that the use of larger rings, higher electric fields and an additional electrode layers can enhance performance.

FIG. 5 illustrates a non-limiting example of a laminated polymer stack 400 comprising additional electrode layers arranged such that alternate electrode layers are connected to a common electrode (+/−). For example, electrode layers 402, 404 and 406 are connected to a common positive (+) electrode and electrode layers 408 and 410 are connected to a common negative (−) electrode. Multiple polymer material layers 412 are shown sandwiched in between the respective electrode layers. The laminated polymer stack provides advantages over a single electrode layer in that it is better suited to applications requiring higher displacement forces.

FIGS. 6A, 6B and 6C are cross-sectional views illustrating how several membrane actuators can be combined to increase the absolute movement and/or force under application of a voltage. In each of the figures, the respective membrane actuators shown include an inner ring 90 such as the inner ring 90 shown in FIG. 3. Further, in each of the figures, four position movements are contemplated (i.e., no excitation, applying a voltage to a first membrane actuator, applying a voltage to a second membrane actuator, and applying a voltage to both the first and second membrane actuators).

Referring first to FIG. 6A, two membrane actuators 500, 552 are shown, connected with a stiff non-conducting cylinder which couples an outer peripheral surface of the actuator's respective inner rings 504, 554. FIG. 5A illustrates the state of the coupled membrane actuators 500, 552 prior to the application of a voltage. The application of a voltage to one or both of the actuators 500, 552 determines the degree and direction of movement. For example, upon applying a voltage to the upper membrane actuator 500, the voltage excitation cases the upper membrane actuator 504 to move in the positive y-direction. This movement is aided by a spring like action. Correspondingly, upon applying a voltage to the lower membrane actuator 552, the coupled membrane actuators move in the negative y-direction. The degree of movement being determined by the voltage potential being applied. Referring now to FIG. 6B, two membrane actuators 600, 662 are shown, connected by a hollow cylinder 602. The configuration of FIG. 5B is suitable for a wide variety of applications. One such application is a lens positioning system in which the actuators 600, 662 are combined in the manner shown in FIG. 5B. In addition, a small lens (not shown) is placed on top of the inner ring 608 of the uppermost membrane actuator 600 and a second small lens (not shown) is placed on top of the inner ring 610 of the lower membrane actuator 662. In operation, a light spot, which is reflected at the bottom by a mirror, goes through the middle of the lower membrane 662 and the hollow cylinder 602. The light is refracted afterwards by the two lenses, which creates an adjustable light spot in dependence of the applied electric field.

Referring now to FIG. 6C, two membrane actuators 700, 762 are shown, connected by a hollow cylinder 702. The astute reader will recognize that the two membrane actuators 700, 762 of FIG. 6C is a variant of that shown in FIG. 6B. In the present configuration, the two membrane actuators 700, 762 are aligned in the same direction.

Of course, in other embodiments, it should be noted that there are no restrictions imposed on the number of couplings or the manner of coupling the multiple membrane actuators.

FIG. 7A-7D, illustrate how an actuator deforms in a single direction upon application of an electric field. As is well known to those knowledgeable in the art, free boundary dielectric polymer deform during an applied electric field equally into both planar direction. However, in a typical application, it is desirable to for a real actuator to generate a certain deformation into a single direction. FIGS. 7A-7D, illustrates how an original polymer material 10 with certain dimensions (as shown in FIG. 7A) is pre-stretched to increase performance and is fixed to a ridged frame (as shown in FIGS. 7B and 7C), which causes the polymer material 10 to become thinner, thereby causing the active deformation to occur in the opposite planar direction (as shown in FIG. 7D). Movement in an intended direction may then be used to perform mechanical work for a specific task.

FIG. 8 is an illustration of a conductive layer 90 (i.e., upper and lower ring electrodes 15, 25, as shown in the various figures) comprised of multiple segments 80. Advantageously, each segment may be sourced from an independent signal, which can be a DC or an AC signal. FIG. 8 also illustrates an elastic, transparent, di-electric membrane 82 and optionally, inner 84 and outer 86 rigid frames for supporting the conductive layer 90.

The present invention further contemplates the use of transparent optical actuators that are covered with transparent upper and lower electrodes to actively generate deformations of a transparent polymer via a DC or AC signal.

The present invention further contemplates the use of a feedback loop to control actuator deformations and displacements by adapting the voltage (or charge) on the electrodes.

Although this invention has been described with reference to particular embodiments, it will be appreciated that many variations will be resorted to without departing from the spirit and scope of this invention as set forth in the appended claims. The scope of the invention is indicated in the appended claims, and all changes that come within the meaning and range of equivalents are intended to be embraced therein. The specification and drawings are accordingly to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof,

f) hardware portions may be comprised of one or both of analog and digital portions;

g) any of the disclosed devices or portions thereof may be combined together or separated into further portions unless specifically stated otherwise; and

h) no specific sequence of acts is intended to be required unless specifically indicated.

What is claimed is:

1. An electroactive polymer actuator (10) for converting electrical energy to mechanical energy, the actuator comprising:
at least two flexible electrodes (15, 25);
a transparent elastic non-conductive material (20) having a substantially constant thickness, the elastic non-conductive material (20) arranged in a manner which causes the elastic non-conductive material (20) to compress in a first direction orthogonal to the thickness in response to an electric field applied to the elastic non-conductive material (20); and
a frame (22) coupled to the at least two electrodes (15, 25) and the elastic non-conductive material (20), the frame (22) substantially preventing expansion in a second direction opposite said first direction in response to an electric field applied to the elastic non-conductive material (20).

2. The electroactive polymer actuator (10) of claim 1, wherein the elastic non-conductive material (20) is a polymer.

3. The electroactive polymer actuator (10) of claim 1, wherein the at least two flexible electrodes (15, 25) are respectively comprised of multiple segments.

4. The electroactive polymer actuator (10) of claim 1, wherein the frame (22) is coupled an edge of the at least two electrodes (15, 25) and the elastic non-conductive material (20).

5. The electroactive polymer actuator (10) of claim 1, further comprising voltage applying means (40) for applying a voltage between said at least two flexible electrodes (15, 25) to cause said compression in said first direction of said elastic non-conductive material (20).

6. The electroactive polymer actuator (10) of claim 3, wherein the voltage applying means (40) is one of a direct current (DC) and alternating current (AC) voltage source.

7. The electroactive polymer actuator (10) of claim 3, wherein the frame (22) is a circular frame.

8. A method of fabricating an electroactive polymer actuator (10), the method comprising:
forming a non-transparent flexible electrode (15) on an upper surface of a transparent elastic non-conductive material (20) in a ring-like pattern excluding a first central region (30); and
forming a non-transparent flexible electrode (25) on a lower surface of the transparent elastic non-conductive material (20) in a ring-like pattern excluding a second central region concentrically arranged with said central region (30).

9. The method of claim 8, further comprising pre-straining the elastic non-conductive material (20) to form a pre-strained elastic non-conductive material.

10. The method of claim 8, wherein the forming of said non-transparent flexible electrodes (15, 25) on said upper and lower surfaces of said elastic non-conductive material (20) comprises one of painting, coating or spraying said non-transparent flexible electrodes (15, 25) on said upper and lower surfaces of said elastic non-conductive material (20) with a flexible conductive material.

11. The method of claim 8, wherein the elastic non-conductive material (20) is a polymer.

12. An aperture diameter structure (10, 300) of a camera diaphragm, comprising:
at least two flexible non-transparent electrodes (15, 25) formed on a respective upper and lower surface of a transparent elastic non-conductive material (20, 130);
said transparent elastic non-conductive material (20, 130) having a substantially constant thickness, the elastic non-conductive material (20, 130) arranged in a manner which causes said transparent elastic non-conductive material (20, 130) to compress in a first direction orthogonal to its thickness in response to an applied electric field; and
a frame (22, 110, 112) coupled to the at least two electrodes (15, 25) and the elastic non-conductive material (20, 130), the frame (22, 110, 112) substantially preventing expansion in a second direction opposite said first direction in response to an electric field applied to the transparent elastic non-conductive material (20, 130).

13. The aperture diameter structure (10, 300) of claim 12, wherein the transparent elastic non-conductive material (20, 130) is a polymer.

14. The aperture diameter structure (10, 300) of claim 12, wherein the frame (22, 110, 112) is coupled an edge of the at least two electrodes (15, 25) and said transparent elastic non-conductive material (20, 130)

15. The aperture diameter structure (10, 300) of claim 12, wherein the electroactive polymer actuator is activated by a voltage source.

16. The aperture diameter structure (10, 300) of claim 15, wherein the voltage source is one of a direct current (DC) and alternating current (AC) voltage source.

17. The aperture diameter structure (10, 300) of claim 12, wherein the frame is circular.

18. An aperture diameter structure (10, 300) of a camera diaphragm, comprising:
at least two flexible electrodes (15, 25) formed on a respective upper and lower surface of a transparent elastic non-conductive material (20, 130);
the transparent elastic non-conductive material (20, 130) having a substantially constant thickness and a hollow central region (30, 90) forming an aperture diameter, the transparent elastic non-conductive material (20, 130) arranged in a manner which causes the transparent elastic non-conductive material (20, 130) to compress in said first direction orthogonal to the thickness in response to an applied electric field thereby changing the diameter of said aperture diameter; and
a frame (22, 110, 112) coupled to the at least two electrodes (15, 25) and the transparent elastic non-conductive material (20, 130), the frame substantially preventing expansion in a second direction opposite said first direction in response to the electric field.

19. The aperture diameter structure (10, 300) of claim 18, wherein the frame is coupled an edge of the at least two electrodes and the elastic non-conductive material.

20. The aperture diameter structure (10, 300) of claim 18, wherein the electroactive polymer actuator is activated by a voltage source (40).

21. The aperture diameter structure (10, 300) of claim 20, wherein the voltage source (40) is one of a direct current (DC) and alternating current (AC) voltage source.

22. The aperture diameter structure (10, 300) of claim 18, wherein the frame (22, 110, 112) is circular.

23. A mechanical system (500, 600, 700) for converting electrical energy to mechanical energy, comprising:
at least two actuators (504, 554, wherein each actuator further comprises:
at least two flexible electrodes;
an elastic non-conductive material having a substantially constant thickness and a hole centrally located in said elastic non-conductive material in a first direction orthogonal to the thickness, the elastic non-conductive material arranged in a manner which causes the elastic non-conductive material to compress in a first direction orthogonal to the thickness in response to an electric field applied to the elastic non-conductive material;
a circular outer frame coupled to an outer edge of the at least two electrodes and the elastic non-conductive material, the circular outer frame substantially preventing expansion in a second direction opposite said first direction orthogonal to the thickness in response to an electric field applied to the elastic non-conductive material,
an inner frame fixedly attached to a perimeter of said hole, the circular inner frame coupled to an inner edge of the at least two electrodes and the elastic non-conductive material,
wherein a first actuator of said at least two actuators is coupled to a second actuator of said at least two actuators by a tubular member.

24. The mechanical system (500, 600, 700) of claim 23, wherein said inner frame is circular.

25. The mechanical system of claim 23, wherein said tubular member is formed by a union of inner frames of each of said respective at least two actuators.

26. The mechanical system of claim 23, wherein the tubular member is a hollow cylindrical tube.

27. The mechanical system of claim 23, wherein said coupled actuators are activated by applying a voltage to one of: (a) said first actuator, (b) said second actuator, (c) said first and second actuators.

28. The mechanical system of claim 23, wherein one of a mass and spring is attached to one of said inner frames to ensure deformation of the polymer in a desired direction.

29. A lens positioning system comprising:
two coupled electroactive polymer actuators (500, 552, 600, 662, 700, 772), the at least two actuators further comprising:
at least two flexible electrodes (15, 25);
an elastic non-conductive material (20, 130) having a substantially constant thickness and a hollow region centrally located in said elastic non-conductive material (20, 130) in a first direction orthogonal to the thickness of the elastic non-conductive material, the elastic non-conductive material (20, 130) arranged in a manner which causes the elastic non-conductive material (20, 130) to compress in a first direction orthogonal to the thickness of the elastic non-conductive material (20, 130) in response to an applied electric field;
an outer frame (22, 110, 112) coupled to an outer edge of the at least two electrodes (15, 25) and the elastic non-conductive material (20, 130), the outer frame (15, 25) substantially preventing expansion in a second direction opposite said first direction in response to the electric field,
an inner frame (92) fixedly attached to a perimeter of said hollow regions (90), the inner frame (90) coupled to an inner edge of the at least two electrodes (15, 25) and the elastic non-conductive material (20, 130),
a hollow cylindrical tube (602, 702, 504, 554)) for coupling said inner frame (90) of said first actuator to said inner frame of said second actuator at a first interface.
a lens attached to said inner frame of one of said at least two flexible electrodes at a second interface.

30. The lens positioning system of claim 29, wherein the elastic non-conductive material is a polymer.
